(19) United States
(12) Patent Application Publication
(10) Pub. No.: US 2020/0194601 A1
(43) Pub. Date: Jun. 18, 2020

(54) COMPOSITION FOR FORMING DIAMOND SAWN WAFER SOLAR CELL ELECTRODE AND DIAMOND SAWN WAFER SOLAR CELL ELECTRODE PREPARED USING THE SAME

(71) Applicant: SAMSUNG SDI CO., LTD., Yongin-si (KR)

(72) Inventors: Jung Chul LEE, Suwon-si (KR); Dae Chan KWON, Suwon-si (KR); Dong Il SHIN, Suwon-si (KR); Min Young LEE, Suwon-si (KR)

(21) Appl. No.: 16/655,731

(22) Filed: Oct. 17, 2019

(30) Foreign Application Priority Data
Dec. 18, 2018 (KR) 10-2018-0164598

(51) Int. Cl. H01L 31/0224; C03C 8/10; C03C 8/04; C03C 8/18; C03C 3/12; C03C 4/14

(52) U.S. Cl. CPC H01L 31/022466; H01L 31/022425; C03C 8/10; C03C 8/04; C03C 2205/00; C03C 3/122; C03C 4/14; C03C 2204/00; C03C 8/18

(57) ABSTRACT

A composition for diamond sawn wafer solar cell electrodes, a diamond sawn wafer solar cell electrode, and method of manufacturing a diamond sawn wafer solar cell, the composition including a conductive powder; a glass frit; and an organic vehicle, wherein the glass frit includes about 10 mol % to about 30 mol % of tellurium oxide, about 10 mol % to about 20 mol % of lithium oxide, and about 5 mol % to about 15 mol % of magnesium oxide.

### CROSS-REFERENCE TO RELATED APPLICATION

Korean Patent Application No. 10-2018-0164598, filed on Dec. 18, 2018, in the Korean Intellectual Property Office, and entitled: “Composition for Forming DSW Based Solar Cell Electrode and DSW Based Solar Cell Electrode Prepared Using the Same,” is incorporated by reference herein in its entirety.

### BACKGROUND

### 1. Field

Embodiments relate to a composition for forming diamond sawn wafer solar cell electrodes and a diamond sawn wafer solar cell electrode prepared using the same.

### 2. Description of the Related Art

Solar cells generate electricity using the photovoltaic effect of a PN junction which converts photons of sunlight into electricity. In a solar cell, front and rear electrodes are formed on respective upper and lower surfaces of a semiconductor wafer or substrate having a PN junction. Then, the photovoltaic effect at the PN junction may be induced by light, e.g., sunlight, entering the semiconductor wafer and electrons generated by the photovoltaic effect at the PN junction provide electric current to the outside through the electrodes. Electrodes of such a solar cell may be formed on a wafer by applying, patterning, and baking a solar cell electrode paste composition.

### SUMMARY

The embodiments may be realized by providing a composition for diamond sawn wafer solar cell electrodes, the composition including a conductive powder; a glass frit; and an organic vehicle, wherein the glass frit includes about 10 mol % to about 30 mol % of tellurium oxide, about 10 mol % to about 20 mol % of lithium oxide, and about 5 mol % to about 15 mol % of magnesium oxide.

The glass frit may further include lead (Pb), bismuth (Bi), phosphorus (P), germanium (Ge), gallium (Ga), cerium (Ce), iron (Fe), silicon (Si), zinc (Zn), tungsten (W), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), or aluminum (Al).

The glass frit may further include about 15 mol % to about 40 mol % of lead oxide.

The glass frit may further include about 5 mol % to about 20 mol % of bismuth oxide.

The glass fit may further include about 5 mol % to about 20 mol % of tungsten oxide.

The glass fit may further include about 0.1 mol % to about 5 mol % of zinc oxide.

The composition may include about 60 wt % to about 95 wt % of the conductive powder; about 0.1 wt % to about 20 wt % of the glass fit; and about 1 wt % to about 30 wt % of the organic vehicle.

The embodiments may be realized by providing a diamond sawn wafer solar cell electrode formed of the composition for diamond sawn wafer solar cell electrodes according to an embodiment.

The glass frit may further include lead (Pb), bismuth (Bi), phosphorus (P), germanium (Ge), gallium (Ga), cerium (Ce), iron (Fe), silicon (Si), zinc (Zn), tungsten (W), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), or aluminum (Al).

The glass frit may further include about 15 mol % to about 40 mol % of lead oxide.

The glass frit may further include about 5 mol % to about 20 mol % of bismuth oxide.

The glass frit may further include about 5 mol % to about 20 mol % of tungsten oxide.

The glass frit may further include about 0.1 mol % to about 5 mol % of zinc oxide.

The composition may include about 60 wt % to about 95 wt % of the conductive powder; about 0.1 wt % to about 20 wt % of the glass frit; and about 1 wt % to about 30 wt % of the organic vehicle.

The electrode may be formed by applying the composition onto a surface of a diamond sawn wafer; and baking the diamond sawn wafer having the composition thereon.

The embodiments may be realized by providing a diamond sawn wafer solar cell including a diamond sawn wafer; and an electrode on at least one surface of the diamond sawn wafer, wherein the electrode is prepared from the composition for diamond sawn wafer solar cell electrodes according to an embodiment.

The embodiments may be realized by providing a method of manufacturing a diamond sawn wafer solar cell, the method including preparing a diamond sawn wafer by sawing the wafer off of an ingot using a diamond wire saw; applying the composition according to an embodiment onto a surface of the diamond sawn wafer; and baking the diamond sawn wafer having the composition thereon.

### BRIEF DESCRIPTION OF THE DRAWINGS

Features will be apparent to those of skill in the art by describing in detail exemplary embodiments with reference to the attached drawings in which:

FIG. 1 illustrates an SEM image of a surface of a diamond sawn wafer.

FIG. 2 illustrates a schematic view of a solar cell according to one embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. Like reference numerals refer to like elements throughout.

As used herein, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. In addition, the singular forms, “a,” “an,” and “the” are intended to include the plural forms as well, unless the context clearly indicates otherwise. As used herein, the term “or” is not an exclusive term, e.g., “A or B” includes A, B, or A and B.

Further, even when not explicitly described, a margin of error is considered in analysis of components.

Further, “X to Y”, as used herein to represent a range of a certain value means “greater than or equal to X and less than or equal to Y” or “≥X and ≤Y”.

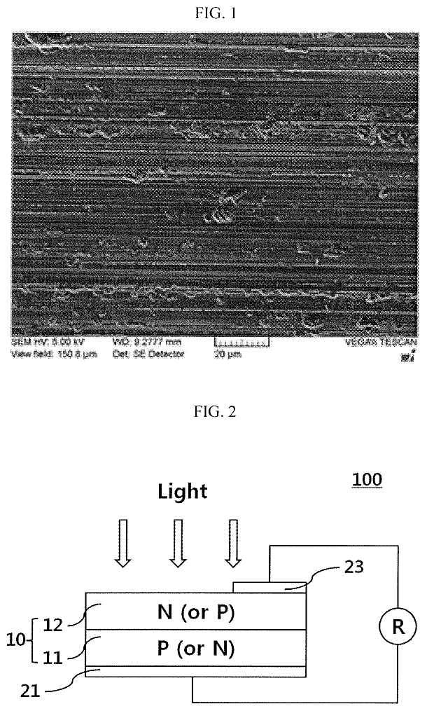

Recently, in manufacture of silicon wafers through slicing of a silicon ingot, diamond-coated wires have been employed in order to increase cutting speed. Wafers obtained by cutting with diamond-coated wires, e.g., diamond sawn wafers (DSWs) have an advantage of low price. Such a DSW may have a rough surface, as shown in FIG. 1, and some electrode pastes could exhibit severe spreading when used in formation of solar cell electrodes on a DSW. For example, a solar cell electrode paste composition according to an embodiment may be suitable for formation of solar cell electrodes on a DSW.

Composition for Diamond Sawn Wafer (DSW) Solar Cell Electrodes

In accordance with an embodiment, a composition for DSW solar cell electrodes may include, e.g., a conductive powder; a glass frit; and an organic vehicle. In an implementation, the glass frit may include, e.g., about 10 mol % to about 30 mol % of tellurium oxide, about 10 mol % to about 20 mol % of lithium oxide, and about 5 mol % to about 15 mol % of magnesium oxide.

Now, each component of the composition for DSW solar cell electrodes according to an embodiment will be described in more detail.

Conductive Powder

The conductive powder may include, e.g., silver (Ag) powder, gold (Au) powder, platinum (Pt) powder, palladium (Pd) powder, aluminum (Al) powder, or nickel (Ni) powder. In an implementation, the conductive powder may include, e.g., silver powder.

In an implementation, the conductive powder may have various particle shapes, e.g., a spherical, flake or amorphous particle shape.

The conductive powder may have a nanometer or micrometer-scale particle size. In an implementation, the conductive powder may have an average particle diameter of dozens to several hundred nanometers, or may have an average particle diameter of several to dozens of micrometers. In an implementation, the conductive powder may be a mixture of two or more types of conductive powder having different particle sizes.

In an implementation, the conductive powder may have an average particle diameter (D₅₀) of, e.g., about 0.1 μm to about 10 μm (for example, about 0.1 μM, about 0.2 μm, about 0.3 μm, about 0.4 μm, about 0.5 μm, about 0.6 μm, about 0.7 μm, about 0.8 μm, about 0.9 μm, about 1 μm, about 2 μm, about 3 μm, about 4 μm, about 5 μm, about 6 μm, about 7 μm, about 8 μm, about 9 μm, or about 10 μm, for another example, about 0.5 μm to about 5 μm). Within this range, the conductive powder may help provide reduction in series resistance and contact resistance. The average particle diameter (D₅₀) may be measured using a Model 1064LD particle size analyzer (CILAS Co., Ltd.) after dispersing the conductive powder in isopropyl alcohol (IPA) at 25° C. for 3 minutes via ultrasonication.

In an implementation, the conductive powder may be present in an amount of, e.g., about 60 wt % to about 95 wt % (for example, about 60 wt %, about 61 wt %, about 62 wt %, about 63 wt %, about 64 wt %, about 65 wt %, about 66 wt %, about 67 wt %, about 68 wt %, about 69 wt %, about 70 wt %, about 71 wt %, about 72 wt %, about 73 wt %, about 74 wt %, about 75 wt %, about 76 wt %, about 77 wt %, about 78 wt %, about 79 wt %, about 80 wt %, about 81 wt %, about 82 wt %, about 83 wt %, about 84 wt %, about 85 wt %, about 86 wt %, about 87 wt %, about 88 wt %, about 89 wt %, about 90 wt %, about 91 wt %, about 92 wt %, about 93 wt %, about 94 wt %, or about 95 wt %, for another example, about 70 wt % to about 90 wt %) based on a total weight of the composition. Within this range, the composition for DSW solar cell electrodes may help improve solar cell conversion efficiency and may be easily prepared in paste form.

Glass Frit

The glass frit may serve to form crystal grains of the conductive powder in an emitter region by etching an anti-reflection layer and melting the conductive powder during a baking process of the composition for solar cell electrodes. The glass frit may help improve adhesion of the conductive powder to a wafer and may be softened to decrease the baking temperature during the baking process.

In an implementation, the glass frit may include, e.g., about 10 mol % to about 30 mol % (for example, about 10 mol %, about 10.1 mol %, about 10.2 mol %, about 10.3 mol %, about 10.4 mol %, about 10.5 mol %, about 10.6 mol %, about 10.7 mol %, about 10.8 mol %, about 10.9 mol %, about 11 mol %, about 11.1 mol %, about 11.2 mol %, about 11.3 mol %, about 11.4 mol %, about 11.5 mol %, about 11.6 mol %, about 11.7 mol %, about 11.8 mol %, about 11.9 mol %, about 12 mol %, about 12.1 mol %, about 12.2 mol %, about 12.3 mol %, about 12.4 mol %, about 12.5 mol %, about 12.6 mol %, about 12.7 mol %, about 12.8 mol %, about 12.9 mol %, about 13 mol %, about 13.1 mol %, about 13.2 mol %, about 13.3 mol %, about 13.4 mol %, about 13.5 mol %, about 13.6 mol %, about 13.7 mol %, about 13.8 mol %, about 13.9 mol %, about 14 mol %, about 14.1 mol %, about 14.2 mol %, about 14.3 mol %, about 14.4 mol %, about 14.5 mol %, about 14.6 mol %, about 14.7 mol %, about 14.8 mol %, about 14.9 mol %, about 15 mol %, about 15.1 mol %, about 15.2 mol %, about 15.3 mol %, about 15.4 mol %, about 15.5 mol %, about 15.6 mol %, about 15.7 mol %, about 15.8 mol %, about 15.9 mol %, about 16 mol %, about 16.1 mol %, about 16.2 mol %, about 16.3 mol %, about 16.4 mol %, about 16.5 mol %, about 16.6 mol %, about 16.7 mol %, about 16.8 mol %, about 16.9 mol %, about 17 mol %, about 17.1 mol %, about 17.2 mol %, about 17.3 mol %, about 17.4 mol %, about 17.5 mol %, about 17.6 mol %, about 17.7 mol %, about 17.8 mol %, about 17.9 mol %, about 18 mol %, about 18.1 mol %, about 18.2 mol %, about 18.3 mol %, about 18.4 mol %, about 18.5 mol %, about 18.6 mol %, about 18.7 mol %, about 18.8 mol %, about 18.9 mol %, about 19 mol %, about 19.1 mol %, about 19.2 mol %, about 19.3 mol %, about 19.4 mol %, about 19.5 mol %, about 19.6 mol %, about 19.7 mol %, about 19.8 mol %, about 19.9 mol %, about 20 mol %, about 20.1 mol %, about 20.2 mol %, about 20.3 mol %, about 20.4 mol %, about 20.5 mol %, about 20.6 mol %, about 20.7 mol %, about 20.8 mol %, about 20.9 mol %, about 21 mol %, about 21.1 mol %, about 21.2 mol %, about 21.3 mol %, about 21.4 mol %, about 21.5 mol %, about 21.6 mol %, about 21.7 mol %, about 21.8 mol %, about 21.9 mol %, about 22 mol %, about 22.1 mol %, about 22.2 mol %, about 22.3 mol %, about 22.4 mol %, about 22.5 mol %, about 22.6 mol %, about 22.7 mol %, about 22.8 mol %, about 22.9 mol %, about 23 mol %, about 23.1 mol %, about 23.2 mol %, about 23.3 mol %, about 23.4 mol %, about 23.5 mol %, about 23.6 mol %, about 23.7 mol %, about 23.8 mol %, about 23.9 mol %, about 24 mol %, about 24.1 mol %, about 24.2 mol %, about 24.3 mol %, about 24.4 mol %, about 24.5 mol %, about 24.6 mol %, about 24.7 mol %, about 24.8 mol %, about 24.9 mol %, about 25 mol %, about 25.1 mol %, about 25.2 mol %, about 25.3 mol %, about 25.4 mol %, about 25.5 mol %, about 25.6 mol %, about 25.7 mol %, about 25.8 mol %, about 25.9 mol %, about 26 mol %, about 26.1 mol %, about 26.2 mol %, about 26.3 mol %, about 26.4 mol %, about 26.5 mol %, about 26.6 mol %, about 26.7 mol %, about 26.8 mol %, about 26.9 mol %, about 27 mol %, about 27.1 mol %, about 27.2 mol %, about 27.3 mol %, about 27.4 mol %, about 27.5 mol %, about 27.6 mol %, about 27.7 mol %, about 27.8 mol %, about 27.9 mol %, about 28 mol %, about 28.1 mol %, about 28.2 mol %, about 28.3 mol %, about 28.4 mol %, about 28.5 mol %, about 28.6 mol %, about 28.7 mol %, about 28.8 mol %, about 28.9 mol %, about 29 mol %, about 29.1 mol %, about 29.2 mol %, about 29.3 mol %, about 29.4 mol %, about 29.5 mol %, about 29.6 mol %, about 29.7 mol %, about 29.8 mol %, about 29.9 mol %, or about 30 mol %) of tellurium oxide, about 10 mol % to about 20 mol % (for example, about 10 mol %, about 10.1 mol %, about 10.2 mol %, about 10.3 mol %, about 10.4 mol %, about 10.5 mol %, about 10.6 mol %, about 10.7 mol %, about 10.8 mol %, about 10.9 mol %, about 11 mol %, about 11.1 mol %, about 11.2 mol %, about 11.3 mol %, about 11.4 mol %, about 11.5 mol %, about 11.6 mol %, about 11.7 mol %, about 11.8 mol %, about 11.9 mol %, about 12 mol %, about 12.1 mol %, about 12.2 mol %, about 12.3 mol %, about 12.4 mol %, about 12.5 mol %, about 12.6 mol %, about 12.7 mol %, about 12.8 mol %, about 12.9 mol %, about 13 mol %, about 13.1 mol %, about 13.2 mol %, about 13.3 mol %, about 13.4 mol %, about 13.5 mol %, about 13.6 mol %, about 13.7 mol %, about 13.8 mol %, about 13.9 mol %, about 14 mol %, about 14.1 mol %, about 14.2 mol %, about 14.3 mol %, about 14.4 mol %, about 14.5 mol %, about 14.6 mol %, about 14.7 mol %, about 14.8 mol %, about 14.9 mol %, about 15 mol %, about 15.1 mol %, about 15.2 mol %, about 15.3 mol %, about 15.4 mol %, about 15.5 mol %, about 15.6 mol %, about 15.7 mol %, about 15.8 mol %, about 15.9 mol %, about 16 mol %, about 16.1 mol %, about 16.2 mol %, about 16.3 mol %, about 16.4 mol %, about 16.5 mol %, about 16.6 mol %, about 16.7 mol %, about 16.8 mol %, about 16.9 mol %, about 17 mol %, about 17.1 mol %, about 17.2 mol %, about 17.3 mol %, about 17.4 mol %, about 17.5 mol %, about 17.6 mol %, about 17.7 mol %, about 17.8 mol %, about 17.9 mol %, about 18 mol %, about 18.1 mol %, about 18.2 mol %, about 18.3 mol %, about 18.4 mol %, about 18.5 mol %, about 18.6 mol %, about 18.7 mol %, about 18.8 mol %, about 18.9 mol %, about 19 mol %, about 19.1 mol %, about 19.2 mol %, about 19.3 mol %, about 19.4 mol %, about 19.5 mol %, about 19.6 mol %, about 19.7 mol %, about 19.8 mol %, about 19.9 mol %, or about 20 mol %) of lithium oxide, and about 5 mol % to about 15 mol % (for example, about 5 mol %, about 5.1 mol %, about 5.2 mol %, about 5.3 mol %, about 5.4 mol %, about 5.5 mol %, about 5.6 mol %, about 5.7 mol %, about 5.8 mol %, about 5.9 mol %, about 6 mol %, about 6.1 mol %, about 6.2 mol %, about 6.3 mol %, about 6.4 mol %, about 6.5 mol %, about 6.6 mol %, about 6.7 mol %, about 6.8 mol %, about 6.9 mol %, about 7 mol %, about 7.1 mol %, about 7.2 mol %, about 7.3 mol %, about 7.4 mol %, about 7.5 mol %, about 7.6 mol %, about 7.7 mol %, about 7.8 mol %, about 7.9 mol %, about 8 mol %, about 8.1 mol %, about 8.2 mol %, about 8.3 mol %, about 8.4 mol %, about 8.5 mol %, about 8.6 mol %, about 8.7 mol %, about 8.8 mol %, about 8.9 mol %, about 9 mol %, about 9.1 mol %, about 9.2 mol %, about 9.3 mol %, about 9.4 mol %, about 9.5 mol %, about 9.6 mol %, about 9.7 mol %, about 9.8 mol %, about 9.9 mol %, about 10 mol %, about 10.1 mol %, about 10.2 mol %, about 10.3 mol %, about 10.4 mol %, about 10.5 mol %, about 10.6 mol %, about 10.7 mol %, about 10.8 mol %, about 10.9 mol %, about 11 mol %, about 11.1 mol %, about 11.2 mol %, about 11.3 mol %, about 11.4 mol %, about 11.5 mol %, about 11.6 mol %, about 11.7 mol %, about 11.8 mol %, about 11.9 mol %, about 12 mol %, about 12.1 mol %, about 12.2 mol %, about 12.3 mol %, about 12.4 mol %, about 12.5 mol %, about 12.6 mol %, about 12.7 mol %, about 12.8 mol %, about 12.9 mol %, about 13 mol %, about 13.1 mol %, about 13.2 mol %, about 13.3 mol %, about 13.4 mol %, about 13.5 mol %, about 13.6 mol %, about 13.7 mol %, about 13.8 mol %, about 13.9 mol %, about 14 mol %, about 14.1 mol %, about 14.2 mol %, about 14.3 mol %, about 14.4 mol %, about 14.5 mol %, about 14.6 mol %, about 14.7 mol %, about 14.8 mol %, about 14.9 mol %, or about 15 mol %) of magnesium oxide. When the glass fit includes tellurium oxide, lithium oxide, and magnesium oxide in the aforementioned amounts, the composition for DSW solar cell electrodes may exhibit reduced spreading when printed on a DSW, and can provide improved properties in terms of open-circuit voltage, series resistance, and fill factor, ultimately improving conversion efficiency of a solar cell. In an implementation, the glass fit may include, e.g., about 15 mol % to about 30 mol % of tellurium oxide, about 15 mol % to about 20 mol % of lithium oxide, and about 5 mol % to about 10 mol % of magnesium oxide.

In an implementation, the glass fit may further include, e.g., lead (Pb), bismuth (Bi), phosphorus (P), germanium (Ge), gallium (Ga), cerium (Ce), iron (Fe), silicon (Si), zinc (Zn), tungsten (W), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), or aluminum (Al).

In an implementation, the glass fit may further include lead oxide in an amount of, e.g., about 15 mol % to about 40 mol % (for example, about 15 mol %, about 15.1 mol %, about 15.2 mol %, about 15.3 mol %, about 15.4 mol %, about 15.5 mol %, about 15.6 mol %, about 15.7 mol %, about 15.8 mol %, about 15.9 mol %, about 16 mol %, about 16.1 mol %, about 16.2 mol %, about 16.3 mol %, about 16.4 mol %, about 16.5 mol %, about 16.6 mol %, about 16.7 mol %, about 16.8 mol %, about 16.9 mol %, about 17 mol %, about 17.1 mol %, about 17.2 mol %, about 17.3 mol %, about 17.4 mol %, about 17.5 mol %, about 17.6 mol %, about 17.7 mol %, about 17.8 mol %, about 17.9 mol %, about 18 mol %, about 18.1 mol %, about 18.2 mol %, about 18.3 mol %, about 18.4 mol %, about 18.5 mol %, about 18.6 mol %, about 18.7 mol %, about 18.8 mol %, about 18.9 mol %, about 19 mol %, about 19.1 mol %, about 19.2 mol %, about 19.3 mol %, about 19.4 mol %, about 19.5 mol %, about 19.6 mol %, about 19.7 mol %, about 19.8 mol %, about 19.9 mol %, about 20 mol %, about 20.1 mol %, about 20.2 mol %, about 20.3 mol %, about 20.4 mol %, about 20.5 mol %, about 20.6 mol %, about 20.7 mol %, about 20.8 mol %, about 20.9 mol %, about 21 mol %, about 21.1 mol %, about 21.2 mol %, about 21.3 mol %, about 21.4 mol %, about 21.5 mol %, about 21.6 mol %, about 21.7 mol %, about 21.8 mol %, about 21.9 mol %, about 22 mol %, about 22.1 mol %, about 22.2 mol %, about 22.3 mol %, about 22.4 mol %, about 22.5 mol %, about 22.6 mol %, about 22.7 mol %, about 22.8 mol %, about 22.9 mol %, about 23 mol %, about 23.1 mol %, about 23.2 mol %, about 23.3 mol %, about 23.4 mol %, about 23.5 mol %, about 23.6 mol %, about 23.7 mol %, about 23.8 mol %, about 23.9 mol %, about 24 mol %, about 24.1 mol %, about 24.2 mol %, about 24.3 mol %, about 24.4 mol %, about 24.5 mol %, about 24.6 mol %, about 24.7 mol %, about 24.8 mol %, about 24.9 mol %, about 25 mol %, about 25.1 mol %, about 25.2 mol %, about 25.3 mol %, about 25.4 mol %, about 25.5 mol %, about 25.6 mol %, about 25.7 mol %, about 25.8 mol %, about 25.9 mol %, about 26 mol %, about 26.1 mol %, about 26.2 mol %, about 26.3 mol %, about 26.4 mol %, about 26.5 mol %, about 26.6 mol %, about 26.7 mol %, about 26.8 mol %, about 26.9 mol %, about 27 mol %, about 27.1 mol %, about 27.2 mol %, about 27.3 mol %, about 27.4 mol %, about 27.5 mol %, about 27.6 mol %, about 27.7 mol %, about 27.8 mol %, about 27.9 mol %, about 28 mol %, about 28.1 mol %, about 28.2 mol %, about 28.3 mol %, about 28.4 mol %, about 28.5 mol %, about 28.6 mol %, about 28.7 mol %, about 28.8 mol %, about 28.9 mol %, about 29 mol %, about 29.1 mol %, about 29.2 mol %, about 29.3 mol %, about 29.4 mol %, about 29.5 mol %, about 29.6 mol %, about 29.7 mol %, about 29.8 mol %, about 29.9 mol %, about 30 mol %, about 30.1 mol %, about 30.2 mol %, about 30.3 mol %, about 30.4 mol %, about 30.5 mol %, about 30.6 mol %, about 30.7 mol %, about 30.8 mol %, about 30.9 mol %, about 31 mol %, about 32.1 mol %, about 32.2 mol %, about 32.3 mol %, about 32.4 mol %, about 32.5 mol %, about 32.6 mol %, about 32.7 mol %, about 32.8 mol %, about 32.9 mol %, about 33 mol %, about 33.1 mol %, about 33.2 mol %, about 33.3 mol %, about 33.4 mol %, about 33.5 mol %, about 33.6 mol %, about 33.7 mol %, about 33.8 mol %, about 33.9 mol %, about 34 mol %, about 34.1 mol %, about 34.2 mol %, about 34.3 mol %, about 34.4 mol %, about 34.5 mol %, about 34.6 mol %, about 34.7 mol %, about 34.8 mol %, about 34.9 mol %, about 35 mol %, about 35.1 mol %, about 35.2 mol %, about 35.3 mol %, about 35.4 mol %, about 35.5 mol %, about 35.6 mol %, about 35.7 mol %, about 35.8 mol %, about 35.9 mol %, about 36 mol %, about 36.1 mol %, about 36.2 mol %, about 36.3 mol %, about 36.4 mol %, about 36.5 mol %, about 36.6 mol %, about 36.7 mol %, about 36.8 mol %, about 36.9 mol %, about 37 mol %, about 37.1 mol %, about 37.2 mol %, about 37.3 mol %, about 37.4 mol %, about 37.5 mol %, about 37.6 mol %, about 37.7 mol %, about 37.8 mol %, about 37.9 mol %, about 38 mol %, about 38.1 mol %, about 38.2 mol %, about 38.3 mol %, about 38.4 mol %, about 38.5 mol %, about 38.6 mol %, about 38.7 mol %, about 38.8 mol %, about 38.9 mol %, about 39 mol %, about 39.1 mol %, about 39.2 mol %, about 39.3 mol %, about 39.4 mol %, about 39.5 mol %, about 39.6 mol %, about 39.7 mol %, about 39.8 mol %, about 39.9 mol %, or about 40 mol %, for another example, about 20 mol % to about 40 mol %). Within this range of amount of lead oxide, the glass fit may help provide a reduction in series resistance.

In an implementation, the glass frit may further include bismuth oxide in an amount of, e.g., about 5 mol % to about 20 mol % (for example, about 5 mol %, about 5.1 mol %, about 5.2 mol %, about 5.3 mol %, about 5.4 mol %, about 5.5 mol %, about 5.6 mol %, about 5.7 mol %, about 5.8 mol %, about 5.9 mol %, about 6 mol %, about 6.1 mol %, about 6.2 mol %, about 6.3 mol %, about 6.4 mol %, about 6.5 mol %, about 6.6 mol %, about 6.7 mol %, about 6.8 mol %, about 6.9 mol %, about 7 mol %, about 7.1 mol %, about 7.2 mol %, about 7.3 mol %, about 7.4 mol %, about 7.5 mol %, about 7.6 mol %, about 7.7 mol %, about 7.8 mol %, about 7.9 mol %, about 8 mol %, about 8.1 mol %, about 8.2 mol %, about 8.3 mol %, about 8.4 mol %, about 8.5 mol %, about 8.6 mol %, about 8.7 mol %, about 8.8 mol %, about 8.9 mol %, about 9 mol %, about 9.1 mol %, about 9.2 mol %, about 9.3 mol %, about 9.4 mol %, about 9.5 mol %, about 9.6 mol %, about 9.7 mol %, about 9.8 mol %, about 9.9 mol %, about 10 mol %, about 10.1 mol %, about 10.2 mol %, about 10.3 mol %, about 10.4 mol %, about 10.5 mol %, about 10.6 mol %, about 10.7 mol %, about 10.8 mol %, about 10.9 mol %, about 11 mol %, about 11.1 mol %, about 11.2 mol %, about 11.3 mol %, about 11.4 mol %, about 11.5 mol %, about 11.6 mol %, about 11.7 mol %, about 11.8 mol %, about 11.9 mol %, about 12 mol %, about 12.1 mol %, about 12.2 mol %, about 12.3 mol %, about 12.4 mol %, about 12.5 mol %, about 12.6 mol %, about 12.7 mol %, about 12.8 mol %, about 12.9 mol %, about 13 mol %, about 13.1 mol %, about 13.2 mol %, about 13.3 mol %, about 13.4 mol %, about 13.5 mol %, about 13.6 mol %, about 13.7 mol %, about 13.8 mol %, about 13.9 mol %, about 14 mol %, about 14.1 mol %, about 14.2 mol %, about 14.3 mol %, about 14.4 mol %, about 14.5 mol %, about 14.6 mol %, about 14.7 mol %, about 14.8 mol %, about 14.9 mol %, about 15 mol %, about 15.1 mol %, about 15.2 mol %, about 15.3 mol %, about 15.4 mol %, about 15.5 mol %, about 15.6 mol %, about 15.7 mol %, about 15.8 mol %, about 15.9 mol %, about 16 mol %, about 16.1 mol %, about 16.2 mol %, about 16.3 mol %, about 16.4 mol %, about 16.5 mol %, about 16.6 mol %, about 16.7 mol %, about 16.8 mol %, about 16.9 mol %, about 17 mol %, about 17.1 mol %, about 17.2 mol %, about 17.3 mol %, about 17.4 mol %, about 17.5 mol %, about 17.6 mol %, about 17.7 mol %, about 17.8 mol %, about 17.9 mol %, about 18 mol %, about 18.1 mol %, about 18.2 mol %, about 18.3 mol %, about 18.4 mol %, about 18.5 mol %, about 18.6 mol %, about 18.7 mol %, about 18.8 mol %, about 18.9 mol %, about 19 mol %, about 19.1 mol %, about 19.2 mol %, about 19.3 mol %, about 19.4 mol %, about 19.5 mol %, about 19.6 mol %, about 19.7 mol %, about 19.8 mol %, about 19.9 mol %, or about 20 mol %, for another example, about 5 mol % to about 15 mol %). Within this range of amount of bismuth oxide, the glass frit may help provide a reduction in series resistance.

In an implementation, the glass frit may further include tungsten oxide in an amount of, e.g., about 5 mol % to about 20 mol % (for example, about 5 mol %, about 5.1 mol %, about 5.2 mol %, about 5.3 mol %, about 5.4 mol %, about 5.5 mol %, about 5.6 mol %, about 5.7 mol %, about 5.8 mol %, about 5.9 mol %, about 6 mol %, about 6.1 mol %, about 6.2 mol %, about 6.3 mol %, about 6.4 mol %, about 6.5 mol %, about 6.6 mol %, about 6.7 mol %, about 6.8 mol %, about 6.9 mol %, about 7 mol %, about 7.1 mol %, about 7.2 mol %, about 7.3 mol %, about 7.4 mol %, about 7.5 mol %, about 7.6 mol %, about 7.7 mol %, about 7.8 mol %, about 7.9 mol %, about 8 mol %, about 8.1 mol %, about 8.2 mol %, about 8.3 mol %, about 8.4 mol %, about 8.5 mol %, about 8.6 mol %, about 8.7 mol %, about 8.8 mol %, about 8.9 mol %, about 9 mol %, about 9.1 mol %, about 9.2 mol %, about 9.3 mol %, about 9.4 mol %, about 9.5 mol %, about 9.6 mol %, about 9.7 mol %, about 9.8 mol %, about 9.9 mol %, about 10 mol %, about 10.1 mol %, about 10.2 mol %, about 10.3 mol %, about 10.4 mol %, about 10.5 mol %, about 10.6 mol %, about 10.7 mol %, about 10.8 mol %, about 10.9 mol %, about 11 mol %, about 11.1 mol %, about 11.2 mol %, about 11.3 mol %, about 11.4 mol %, about 11.5 mol %, about 11.6 mol %, about 11.7 mol %, about 11.8 mol %, about 11.9 mol %, about 12 mol %, about 12.1 mol %, about 12.2 mol %, about 12.3 mol %, about 12.4 mol %, about 12.5 mol %, about 12.6 mol %, about 12.7 mol %, about 12.8 mol %, about 12.9 mol %, about 13 mol %, about 13.1 mol %, about 13.2 mol %, about 13.3 mol %, about 13.4 mol %, about 13.5 mol %, about 13.6 mol %, about 13.7 mol %, about 13.8 mol %, about 13.9 mol %, about 14 mol %, about 14.1 mol %, about 14.2 mol %, about 14.3 mol %, about 14.4 mol %, about 14.5 mol %, about 14.6 mol %, about 14.7 mol %, about 14.8 mol %, about 14.9 mol %, about 15 mol %, about 15.1 mol %, about 15.2 mol %, about 15.3 mol %, about 15.4 mol %, about 15.5 mol %, about 15.6 mol %, about 15.7 mol %, about 15.8 mol %, about 15.9 mol %, about 16 mol %, about 16.1 mol %, about 16.2 mol %, about 16.3 mol %, about 16.4 mol %, about 16.5 mol %, about 16.6 mol %, about 16.7 mol %, about 16.8 mol %, about 16.9 mol %, about 17 mol %, about 17.1 mol %, about 17.2 mol %, about 17.3 mol %, about 17.4 mol %, about 17.5 mol %, about 17.6 mol %, about 17.7 mol %, about 17.8 mol %, about 17.9 mol %, about 18 mol %, about 18.1 mol %, about 18.2 mol %, about 18.3 mol %, about 18.4 mol %, about 18.5 mol %, about 18.6 mol %, about 18.7 mol %, about 18.8 mol %, about 18.9 mol %, about 19 mol %, about 19.1 mol %, about 19.2 mol %, about 19.3 mol %, about 19.4 mol %, about 19.5 mol %, about 19.6 mol %, about 19.7 mol %, about 19.8 mol %, about 19.9 mol %, or about 20 mol %, for another example, about 5 mol % to about 15 mol %). Within this range of amount of tungsten oxide, the composition may exhibit good adhesive strength.

In an implementation, the glass fit may further include zinc oxide in an amount of, e.g., about 0.1 mol % to about 5 mol % (for example, about 0.1 mol %, about 0.2 mol %, about 0.3 mol %, about 0.4 mol %, about 0.5 mol %, about 0.6 mol %, about 0.7 mol %, about 0.8 mol %, about 0.9 mol %, about 1 mol %, about 1.1 mol %, about 1.2 mol %, about 1.3 mol %, about 1.4 mol %, about 1.5 mol %, about 1.6 mol %, about 1.7 mol %, about 1.8 mol %, about 1.9 mol %, about 2 mol %, about 2.1 mol %, about 2.2 mol %, about 2.3 mol %, about 2.4 mol %, about 2.5 mol %, about 2.6 mol %, about 2.7 mol %, about 2.8 mol %, about 2.9 mol %, about 3 mol %, about 3.1 mol %, about 3.2 mol %, about 3.3 mol %, about 3.4 mol %, about 3.5 mol %, about 3.6 mol %, about 3.7 mol %, about 3.8 mol %, about 3.9 mol %, about 4 mol %, about 4.1 mol %, about 4.2 mol %, about 4.3 mol %, about 4.4 mol %, about 4.5 mol %, about 4.6 mol %, about 4.7 mol %, about 4.8 mol %, about 4.9 mol %, or about 5 mol %, for another example, about 0.5 mol % to about 5 mol %). Within this range of amount of zinc oxide, the composition may exhibit good adhesive strength.

In an implementation, the glass frit may include lead oxide and bismuth oxide, and, optionally tungsten oxide and/or zinc oxide.

In an implementation, the glass frit may have a spherical or amorphous shape and may have an average particle diameter (D₅₀) of, e.g., about 0.1 μm to about 10 μm (for example, about 0.1 μm, about 0.2 μm, about 0.3 μm, about 0.4 μm, about 0.5 μm, about 0.6 μm, about 0.7 μm, about 0.8 μm, about 0.9 μm, about 1 μm, about 2 μm, about 3 μm, about 4 μm, about 5 μm, about 6 μm, about 7 μm, about 8 μm, about 9 μm, or about 10 μm). The average particle diameter (D₅₀) may be measured using a Model 1064LD particle size analyzer (CILAS Co., Ltd.) after dispersing the glass frit in isopropyl alcohol (IPA) at 25° C. for 3 minutes via ultrasonication. In an implementation, the glass frit may be prepared from, e.g., tellurium oxide, lithium oxide and magnesium oxide, and, optionally the aforementioned metals and/or oxides thereof by a suitable method. In an implementation, the glass fit may be prepared by mixing tellurium oxide, lithium oxide and magnesium oxide, and, optionally the aforementioned metals and/or oxides thereof using a ball mill or a planetary mill, melting the mixture at 800° C. to 1,300° C., and quenching the melted mixture to 25° C., followed by pulverizing the obtained product using a disk mill, a planetary mill, or the like.

In an implementation, the glass fit may be present in an amount of, e.g., about 0.1 wt % to about 20 wt % (for example, about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, about 1.1 wt %, about 1.2 wt %, about 1.3 wt %, about 1.4 wt %, about 1.5 wt %, about 1.6 wt %, about 1.7 wt %, about 1.8 wt %, about 1.9 wt %, about 2 wt %, about 2.1 wt %, about 2.2 wt %, about 2.3 wt %, about 2.4 wt %, about 2.5 wt %, about 2.6 wt %, about 2.7 wt %, about 2.8 wt %, about 2.9 wt %, about 3 wt %, about 4 wt %, about 5 wt %, about 6 wt %, about 7 wt %, about 8 wt %, about 9 wt %, about 10 wt %, about 11 wt %, about 12 wt %, about 13 wt %, about 14 wt %, about 15 wt %, about 16 wt %, about 17 wt %, about 18 wt %, about 19 wt %, or about 20 wt %, for another example, about 0.5 wt % to about 10 wt %) based on the total weight of the composition. Within this range, the glass frit may help secure stability of a p-n junction under various sheet resistances, minimize resistance, and ultimately improve solar cell efficiency.

Organic Vehicle

The organic vehicle may impart suitable viscosity and rheological characteristics for printing to the composition for DSW solar cell electrodes through mechanical mixing with inorganic components of the composition.

The organic vehicle may be a suitable organic vehicle used in a composition for solar cell electrodes, and may include, e.g., a binder resin, a solvent, or the like.

The binder resin may include, e.g., acrylate resins or cellulose resins. For example, ethyl cellulose may be used as the binder resin. In an implementation, the binder resin may include, e.g., ethyl hydroxyethyl cellulose, nitrocellulose, blends of ethyl cellulose and phenol resins, alkyd resins, phenol resins, acrylate ester resins, xylene resins, polybutene resins, polyester resins, urea resins, melamine resins, vinyl acetate resins, wood rosin, polymethacrylates of alcohols, or the like.

In an implementation, the solvent may include, e.g., hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzylalcohol, γ-butyrolactone, ethyl lactate, and 2,2,4-trimethyl-1,3-pentanediol monoisobutyrate (Texanol). These may be used alone or as a mixture thereof.

In an implementation, the organic vehicle may be present in an amount of, e.g., about 1 wt % to about 30 wt % (for example, about 1 wt %, about 2 wt %, about 3 wt %, about 4 wt %, about 5 wt %, about 6 wt %, about 7 wt %, about 8 wt %, about 9 wt %, about 10 wt %, about 11 wt %, about 12 wt %, about 13 wt %, about 14 wt %, about 15 wt %, about 16 wt %, about 17 wt %, about 18 wt %, about 19 wt %, about 20 wt %, about 21 wt %, about 22 wt %, about 23 wt %, about 24 wt %, about 25 wt %, about 26 wt %, about 27 wt %, about 28 wt %, about 29 wt %, or about 30 wt %, for another example, about 3 wt % to about 20 wt %) based on the total weight of the composition for DSW solar cell electrodes. Within this range, the organic vehicle may help provide sufficient adhesive strength and good printability to the composition.

Additive

In an implementation, the composition for DSW solar cell electrodes may further include a suitable additive to help enhance flowability, processability and stability, as desired. In an implementation, the additive may include, e.g., a dispersant, a thixotropic agent, a plasticizer, a viscosity stabilizer, an anti-foaming agent, a pigment, a UV stabilizer, an antioxidant, a coupling agent, or the like. These may be used alone or as a mixture thereof. In an implementation, the additive may be present in an amount of, e.g., about 0.1 wt % to about 5 wt % (for example, about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, about 2 wt %, about 3 wt %, about 4 wt %, or about 5 wt %) based on the total weight of the composition for DSW solar cell electrodes.

DSW Solar Cell Electrode and DSW Solar Cell Including the Same

Another embodiment may provide a DSW solar cell electrode formed of or prepared from the composition for DSW solar cell electrodes, and a DSW solar cell including the same. FIG. 2 illustrates a schematic view of a solar cell 100 according to one embodiment.

Referring to FIG. 2, a rear electrode 21 and/or a front electrode 23 may be formed by printing and baking the composition for DSW solar cell electrodes on a DSW 10 that includes a p-layer (or n-layer) 11 and an n-layer (or p-layer) 12, which will serve as an emitter. For example, a preliminary process for preparing the front electrode may be performed by printing the composition for DSW solar cell electrodes on a front surface of the DSW, followed by drying. Further, a preliminary process for preparing the rear electrode may be performed by printing the composition for DSW solar cell electrodes on a back surface of the DSW, followed by drying at about 200° C. to about 400° C. for about 10 to about 60 seconds. Then, the front electrode and the rear electrode may be formed by baking the DSW at about 400° C. to about 970° C., e.g., at about 600° C. to about 970° C., for about 30 to about 210 seconds.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLE

### Example 1

As a binder resin, 2 parts by weight of ethyl cellulose (STD4, Dow Chemical Company) was sufficiently dissolved in 6.5 parts by weight of terpineol (Nippon Terpine Co., Ltd.) at 60° C., and 90 parts by weight of spherical silver powder (AG-5-11F, Dowa Hightech Co. Ltd.) having an average particle diameter of 2.0 μm, as a conductive powder, and 1.5 parts by weight of glass fit A having an average particle diameter of 2.0 μm and components and amounts as shown in Table 1, were added to the binder solution, followed by mixing and kneading in a 3-roll kneader, thereby preparing a composition for solar cell electrodes.

### Examples 2 and 3 and Comparative Examples 1 to 10

Compositions for solar cell electrodes were prepared in the same manner as in Example 1 except that glass frits B to M listed in Table 1 were used instead of glass frit A.

TABLE 1

| | PbO | Bi₂O₃ | TeO₂ | WO₃ | Li₂O | ZnO | MgO |
|---|---|---|---|---|---|---|---|
| Glass frit A | 20 | 10 | 25 | 15 | 17 | 3 | 10 |
| Glass frit B | 23 | 10 | 30 | 10 | 17 | — | 10 |
| Glass frit C | 32 | 10 | 21 | 15 | 15 | — | 7 |
| Glass frit D | — | 5 | 48 | 5 | 20 | 18 | 4 |
| Glass frit E | 5 | — | 50 | 2 | 20 | 15 | 8 |
| Glass frit F | 10 | — | 55 | — | 15 | 15 | 5 |
| Glass frit G | 45 | — | 36 | — | 5 | 12 | 2 |
| Glass frit H | 48 | 10 | 5 | 10 | 17 | — | 10 |
| Glass frit I | 18 | 10 | 35 | 10 | 17 | — | 10 |
| Glass frit J | 35 | 10 | 30 | 10 | 5 | — | 10 |
| Glass frit K | 20 | 10 | 30 | 10 | 23 | — | 7 |
| Glass frit L | 32 | 10 | 30 | 10 | 17 | — | 1 |
| Glass frit M | 22 | 10 | 30 | 10 | 12 | — | 16 |

*Unit: mol %

Property Evaluation

(1) Short-circuit current (Isc, A), open-circuit voltage (Voc, V), and series resistance (Rs, Ω): Each of the compositions for solar cell electrodes prepared in Examples 1 to 3 and Comparative Examples 1 to 10 was deposited over a front surface of a DSW by screen printing in a predetermined pattern, followed by drying in an IR drying furnace at 300° C. A cell formed according to this procedure was baked in a belt-type baking furnace at a temperature of 970° C. for 70 seconds, thereby fabricating a solar cell. The solar cell was evaluated as to short-circuit current, open-circuit voltage, and series resistance using a solar cell efficiency tester CT-801 (Pasan Co., Ltd.). Results are shown in Table 2.

(2) Fill factor (FF, %) and conversion efficiency (Eff., %): Aluminum paste was printed on a back surface of a DSW (a multicrystalline wafer prepared by texturing a front surface of a p-type wafer doped with boron, forming an n⁺ layer of POCl₃ on the textured surface, and forming an anti-reflection film of silicon nitride (SiNₓ:H) on the n⁺ layer), followed by drying at 300° C. Then, each of the compositions for solar cell electrodes prepared in Examples 1 to 3 and Comparative Examples 1 to 10 was deposited over a front surface of the DSW by screen printing in a predetermined pattern, followed by drying in the same manner as above. A cell formed according to this procedure was baked in a belt-type baking furnace at 970° C. for 70 seconds, thereby fabricating a solar cell. The solar cell was evaluated as to fill factor and conversion efficiency using a solar cell efficiency tester (Flash Simulator, H.A.L.M.). Results are shown in Table 2.

TABLE 2

| | Isc (A) | Voc (V) | Rs (ohm) | FF (%) | Eff. (%) |
|---|---|---|---|---|---|
| Example 1 | 8.918 | 637.500 | 2.50 | 78.80 | 18.50 |
| Example 2 | 8.903 | 637.700 | 2.70 | 79.61 | 18.60 |
| Example 3 | 8.909 | 637.000 | 2.40 | 79.83 | 18.75 |
| Comparative | 8.908 | 636.300 | 3.87 | 76.86 | 17.91 |
| Example 1 | | | | | |
| Comparative | 8.906 | 635.200 | 8.51 | 71.27 | 16.70 |
| Example 2 | | | | | |
| Comparative | 8.909 | 634.500 | 15.36 | 63.19 | 14.83 |
| Example 3 | | | | | |
| Comparative | 8.907 | 634.000 | 18.50 | 59.72 | 14.24 |
| Example 4 | | | | | |
| Comparative | 8.904 | 634.200 | 5.36 | 73.45 | 17.85 |
| Example 5 | | | | | |
| Comparative | 8.876 | 634.400 | 14.50 | 59.34 | 13.44 |
| Example 6 | | | | | |
| Comparative | 8.765 | 633.500 | 5.36 | 73.19 | 17.33 |
| Example 7 | | | | | |
| Comparative | 8.988 | 633.800 | 8.50 | 69.54 | 15.94 |
| Example 8 | | | | | |
| Comparative | 8.859 | 633.600 | 5.34 | 73.33 | 16.93 |
| Example 9 | | | | | |
| Comparative | 8.845 | 632.000 | 12.30 | 69.72 | 14.45 |
| Example 10 | | | | | |

From the results shown in Table 2, it may be seen that the solar cell electrodes fabricated using the compositions of Examples 1 to 3, including tellurium oxide, lithium oxide, and magnesium oxide in the amounts set forth herein, exhibited improved properties in terms of open-circuit voltage and series resistance and exhibited good fill factor and conversion efficiency, as compared with the solar cell electrodes fabricated using the compositions of Comparative Examples 1 to 10, in which the amount of at least one of tellurium oxide, lithium oxide, and magnesium oxide did not fell within the range set forth herein.

By way of summation and review, continuous reduction in emitter thickness for improvement of solar cell efficiency may cause shunting, which could deteriorate solar cell performance. In addition, despite providing an increase in open-circuit voltage, the reduction in emitter thickness could cause increase in contact resistance and series resistance of an electrode, eventually resulting in deterioration in solar cell efficiency. For example, in order to secure stable solar cell conversion efficiency under high sheet resistances, an electrode paste composition may help minimize series resistance and adverse effects on open-circuit voltage while preventing damage to a PN junction.

One or more embodiments may provide a composition for diamond sawn wafer solar cell electrodes, which exhibits reduced spreading.

One or more embodiments may provide a composition for diamond sawn wafer solar cell electrodes, which can exhibit improved properties in terms of open-circuit voltage, series resistance, and fill factor, thereby improving solar cell conversion efficiency.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A composition for diamond sawn wafer solar cell electrodes, the composition comprising:
a conductive powder;
a glass frit; and
an organic vehicle,
wherein the glass frit includes:
about 10 mol % to about 30 mol % of tellurium oxide,
about 10 mol % to about 20 mol % of lithium oxide, and
about 5 mol % to about 15 mol % of magnesium oxide.

2. The composition as claimed in claim 1, wherein the glass frit further includes lead (Pb), bismuth (Bi), phosphorus (P), germanium (Ge), gallium (Ga), cerium (Ce), iron (Fe), silicon (Si), zinc (Zn), tungsten (W), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), or aluminum (Al).

3. The composition as claimed in claim 1, wherein the glass frit further includes about 15 mol % to about 40 mol % of lead oxide.

4. The composition as claimed in claim 1, wherein the glass frit further includes about 5 mol % to about 20 mol % of bismuth oxide.

5. The composition as claimed in claim 1, wherein the glass frit further includes about 5 mol % to about 20 mol % of tungsten oxide.

6. The composition as claimed in claim 1, wherein the glass frit further includes about 0.1 mol % to about 5 mol % of zinc oxide.

7. The composition as claimed in claim 1, wherein the composition includes:
about 60 wt % to about 95 wt % of the conductive powder;
about 0.1 wt % to about 20 wt % of the glass fit; and
about 1 wt % to about 30 wt % of the organic vehicle.

8. A diamond sawn wafer solar cell electrode formed of the composition for diamond sawn wafer solar cell electrodes as claimed in claim 1.

9. The electrode as claimed in claim 8, wherein the glass frit further includes lead (Pb), bismuth (Bi), phosphorus (P), germanium (Ge), gallium (Ga), cerium (Ce), iron (Fe), silicon (Si), zinc (Zn), tungsten (W), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), or aluminum (Al).

10. The electrode as claimed in claim 8, wherein the glass frit further includes about 15 mol % to about 40 mol % of lead oxide.

11. The electrode as claimed in claim 8, wherein the glass frit further includes about 5 mol % to about 20 mol % of bismuth oxide.

12. The electrode as claimed in claim 8, wherein the glass frit further includes about 5 mol % to about 20 mol % of tungsten oxide.

13. The electrode as claimed in claim 8, wherein the glass frit further includes about 0.1 mol % to about 5 mol % of zinc oxide.

14. A method of manufacturing a diamond sawn wafer solar cell, the method comprising:
preparing a diamond sawn wafer by sawing the wafer off of an ingot using a diamond wire saw;
applying the composition as claimed in claim 1 onto a surface of the diamond sawn wafer; and
baking the diamond sawn wafer having the composition thereon.
